(19) United States
(12) Patent Application Publication
(10) Pub. No.: US 2025/0132220 A1
(43) Pub. Date: Apr. 24, 2025

(54) ELECTRONIC DEVICES AND A METHODS OF MANUFACTURING ELECTRONIC DEVICES

(71) Applicant: Amkor Technology Singapore Holding Pte. Ltd., Singapore (SG)

(72) Inventors: Dong Hyeon Park, Seoul (KR); Yu Jin Jeon, Incheon (KR); Ji Young Jeong, Gyeonggi-do (KR); Dong Su Ryu, Incheon (KR); Byoung Woo Cho, Seoul (KR); Jo Hyun Bae, Incheon (KR); Min Jae Kong, Seoul (KR)

(73) Assignee: Amkor Technology Singapore Holding Pte. Ltd., Singapore (SG)

(21) Appl. No.: 18/490,524

(22) Filed: Oct. 19, 2023

(51) Int. Cl. H01L 23/367; H01L 21/54; H01L 21/56; H01L 23/00; H01L 23/42

(52) U.S. Cl. CPC H01L 23/3675; H01L 21/54; H01L 23/42; H01L 24/04; H01L 24/05; H01L 24/06; H01L 24/29; H01L 24/32; H01L 24/83; H01L 21/563; H01L 24/13; H01L 24/16; H01L 24/30; H01L 24/33; H01L 24/73; H01L 24/81; H01L 24/92; H01L 2224/0401; H01L 2224/04026; H01L 2224/05644; H01L 2224/05647; H01L 2224/05655; H01L 2224/05666; H01L 2224/0603; H01L 2224/13111; H01L 2224/13116; H01L 2224/13147; H01L 2224/13186; H01L 2224/16227; H01L 2224/29105; H01L 2224/29109; H01L 2224/29111; H01L 2224/29118; H01L 2224/29139; H01L 2224/30505; H01L 2224/32225; H01L 2224/32245; H01L 2224/33181; H01L 2224/73204; H01L 2224/73253; H01L 2224/81203; H01L 2224/81224; H01L 2224/81411; H01L 2224/81439; H01L 2224/81444; H01L 2224/81447; H01L 2224/81455; H01L 2224/8146; H01L 2224/81464; H01L 2224/81815; H01L 2224/831; H01L 2224/83191; H01L 2224/83424; H01L 2224/83447; H01L 2224/83455; H01L 2224/83986; H01L 2224/92125; H01L 2224/92225; H01L 2924/01015; H01L 2924/0132; H01L 2924/014; H01L 2924/0521

(57) ABSTRACT

In one example, an electronic device comprises a substrate comprising a dielectric structure and a conductive structure, a first electronic component over a top side of the substrate and coupled with the conductive structure, a lid over the first electronic component and coupled with a top side of the substrate, wherein the lid comprises a top plate having a plurality of holes, and a covering material covering a lateral side of the first electronic component and extending between the top side of the substrate and a bottom side of the top plate of the lid. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2F show cross-sectional views of an example method for manufacturing an example electronic device.

FIG. 3 shows a cross-sectional view of an example electronic device.

FIG. 4 shows a cross-sectional view of an example electronic device.

FIGS. 5A to 5E show cross-sectional views of an example method for manufacturing an example electronic device.

FIG. 6 shows a cross-sectional view of an example electronic device.

The following discussion provides various examples of electronic devices and methods of manufacturing electronic devices. Such examples are non-limiting, and the scope of the appended claims should not be limited to the particular examples disclosed. In the following discussion, the terms “example” and “e.g.,” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprise”, “comprises”, “comprising”, “include”, “includes”, and “including” are “open ended” terms and specify the presence of stated features, but do not preclude the presence or addition of one or more other features. The terms “first”, “second”, and so on can be used herein to describe various elements; however, the described elements shall not be limited by these terms. These terms are only used to distinguish one element from another. Thus, for example, a first element discussed in the present disclosure could be termed a second element without departing from the teachings of the present disclosure.

Unless specified otherwise, the term “coupled” can be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” can be used to describe two elements directly contacting each other or describe two elements indirectly coupled by one or more other elements. As used herein, the term “coupled” can refer to an electrical or mechanical coupling.

### DESCRIPTION

In one example, an electronic device comprises a substrate comprising a dielectric structure and a conductive structure, a first electronic component over a top side of the substrate and coupled with the conductive structure, a lid over the first electronic component and coupled with a top side of the substrate. The lid comprises a top plate having a plurality of holes, and a covering material covering a lateral side of the first electronic component and extending between the top side of the substrate and a bottom side of the top plate of the lid.

In another example, an electronic device comprises a substrate comprising a dielectric structure and a conductive structure, a first electronic component over a top side of the substrate and coupled with the conductive structure, a lid over the first electronic component and coupled with a top side of the substrate, wherein the lid comprises a top plate having a plurality of holes, and a covering material covering a lateral side of the first electronic component.

In a further example, a method to manufacture an electronic device comprises providing a substrate comprising a dielectric structure and a conductive structure, providing a first electronic component over a top side of the substrate and coupled with the conductive structure, providing a lid over the first electronic component and coupled with a top side of the substrate, wherein the lid comprises a top plate having a plurality of holes, and providing a covering material into one of the plurality of holes. The covering material covers a lateral side of the first electronic component and extends from the top side of the substrate to the top plate of the lid.

Other examples are included in the present disclosure. Such examples may be found in the figures, in the claims, or in the description of the present disclosure.

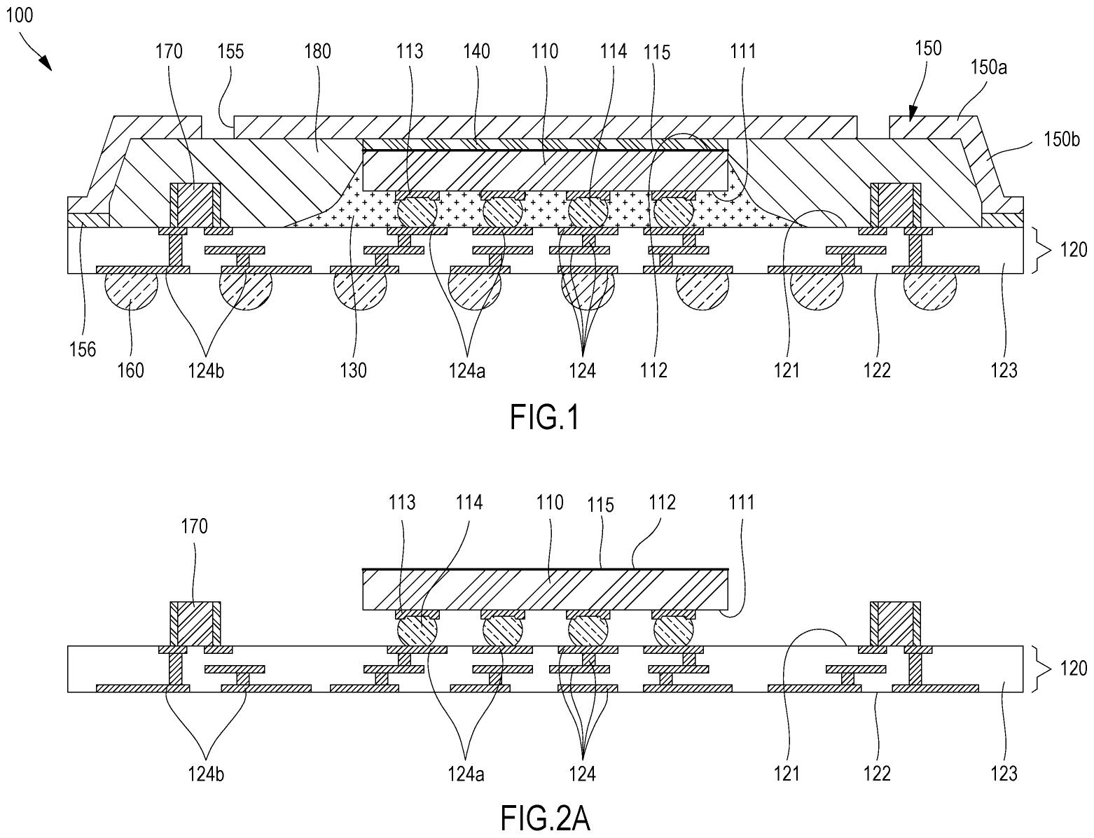

FIG. 1 shows a cross-sectional view of electronic device 100. In the example shown in FIG. 1, electronic device 100 can comprise electronic component 110, substrate 120, underfill 130, thermal interface material (TIM) 140, lid 150, external interconnects 160, and infilling material 180. In some examples, electronic device 100 can comprise electronic components 170 which can comprise passive or active components.

Electronic component 110 can comprise side 111 and side 112 opposite side 111. Electronic component 110 can comprise contact pads 113 and connectors 114. Substrate 120 can comprise inward side 121 and outward side 122 opposite inward side 121. Substrate 120 can comprise dielectric structure 123 and conductive structure 124. Electronic component 110 can be over the top side or inward side 121 of substrate 120 and can be coupled with conductive structure 124. Conductive structure 124 can comprise substrate inward terminals 124a and substrate outward terminals 124b. Lid 150 can comprise lid holes 155 and lid adhesive 156. Lid 150 can comprise top plate 150a and sidewall 150b. Top plate 150a of lid 150 can comprise a plurality of lid holes 155. Lid 150 can be over electronic component 110 and can be coupled with the top side or inward side 121 of substrate 120. Infilling material 180 can comprise a covering material covering a lateral side of electronic component 110. Infilling material 180 can extend between a top side or inward side 121 of substrate 120 and the bottom side of lid 150 or top plate 150a of lid. In some examples, the covering material can comprise TIM 140 and infilling material 180 surrounding TIM 140. In some examples, electronic component 170 can be over the top side or inward side 121 of substrate 120 and can be coupled with conductive structure 124. In some examples, covering material such as infilling material 180 can cover a lateral side of electronic component 170.

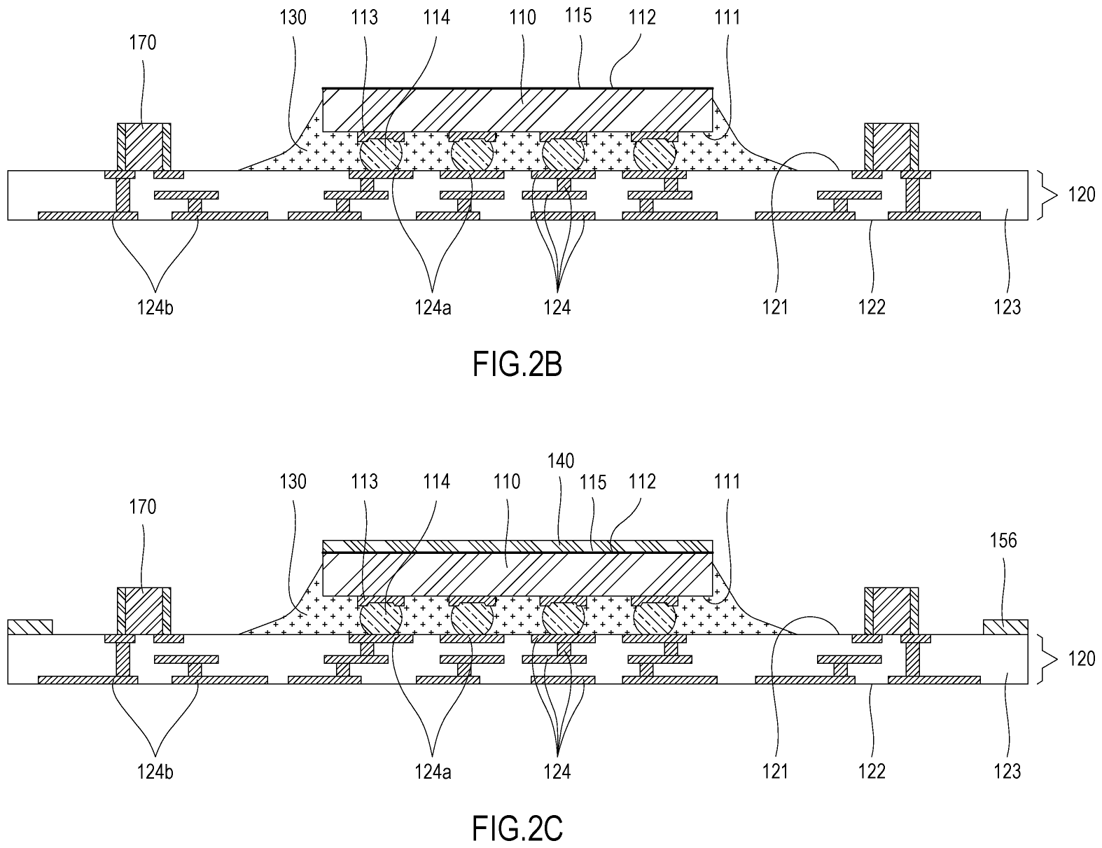

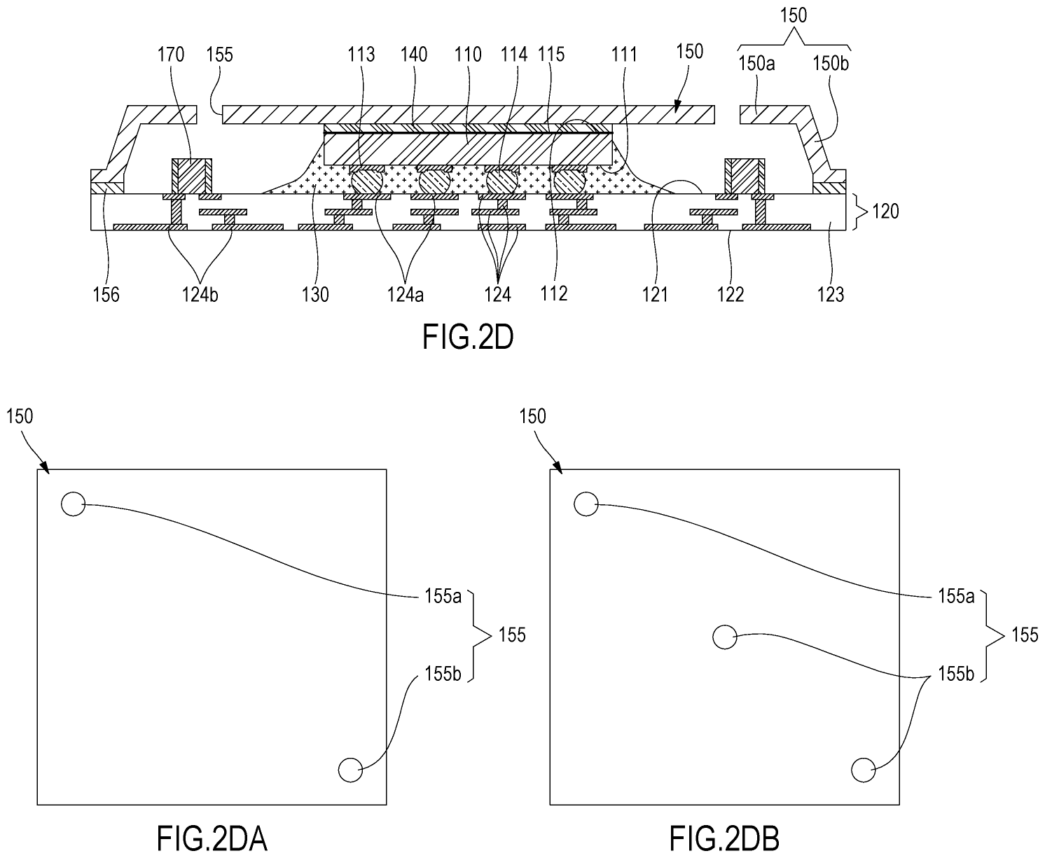

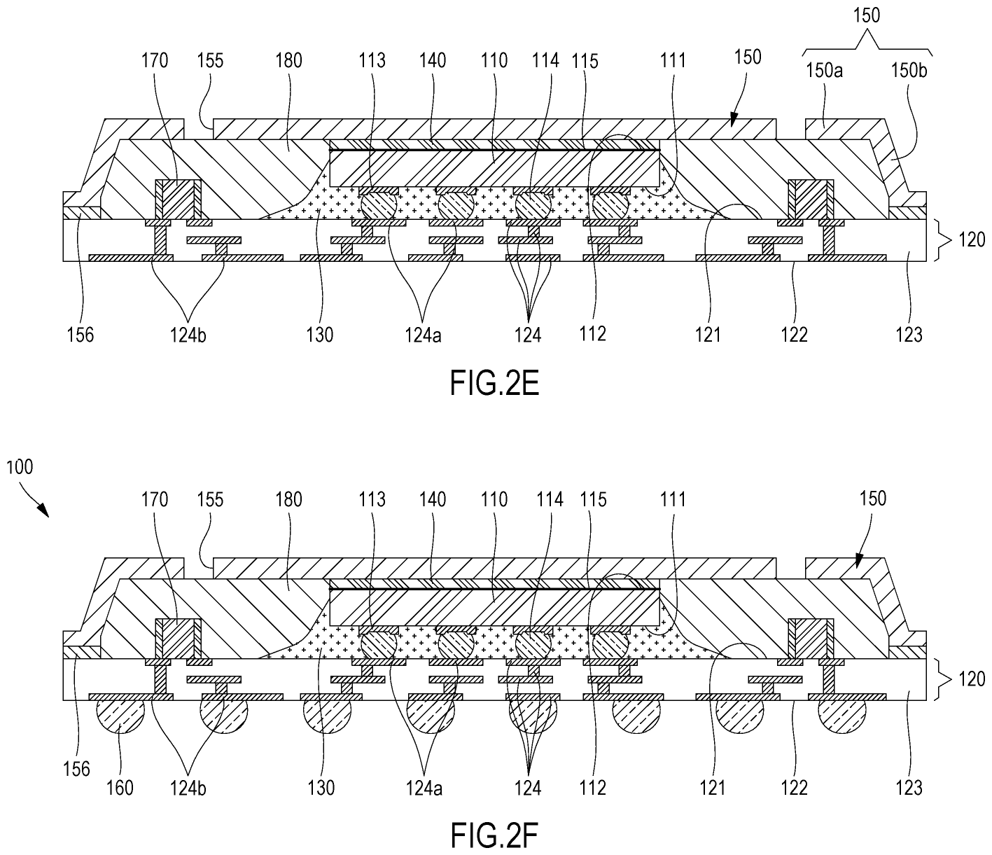

FIGS. 2A to 2F show cross-sectional views of an example method for manufacturing example electronic device 100. FIG. 2A shows a cross-sectional view of electronic device 100 at an early stage of manufacture. In the example shown in FIG. 2A, electronic component 110 can be provided on inward side 121 of substrate 120. In some examples, electronic components 170 can be provided on inward side 121 or outward side 122 of substrate 120.

Substrate 120 can comprise dielectric structure 123 and conductive structure 124. In some examples, dielectric structure 123 can comprise or be referred to as one or more stacked dielectric layers. For instance, the one or more dielectric layers can comprise, one or more core layers, polymer layers, pre-preg layers, or solder mask layers stacked on each other. One or more layers or elements of conductive structure 124 can be interleaved with dielectric structure 123. In some examples, dielectric structure 123 can comprise or be referred to as polyimide (PI), benzocyclobutene (BCB), polybenzoxazole (PBO), resin, Ajinomoto Buildup Film (ABF), epoxy, or ceramic. In some examples, the thickness of dielectric structure 123 can range from approximately 10 micrometers (μm) to 1000 μm.

Conductive structure 124 can comprise one or more conductive layers and can define conductive paths with elements such as traces, pads, vias, or wiring patterns. Conductive structure 124 can comprise substrate inward terminals 124a provided on inward side 121 of substrate 120, or substrate outward terminals 124b provided on outward side 122 of substrate 120.

Substrate inward terminals 124a can be provided on inward side 121 of substrate 120, and substrate outward terminals 124b can be provided outward side 122 of substrate 120. In some examples, substrate inward terminals 124a or substrate outward terminals 124b can be arranged in a matrix pattern, for example provided in rows or columns. In some examples, substrate inward terminals 124a and substrate outward terminals 124b can comprise or be referred to as a conductor, a conductive material, a substrate land, a conductive land, a substrate pad, a wiring pad, a connection pad, a micro pad, or under-bump-metallurgy (UBM). In some examples, the thicknesses of substrate inward terminals 124a or substrate outward terminals 124b can each range from approximately 1 μm to 100 μm. Conductive structure 124 can be provided in dielectric structure 123 to couple substrate inward terminals 124a with substrate outward terminals 124b. In some examples, conductive structure 123 can comprise copper, iron, nickel, gold, silver, palladium, or tin.

In some examples, substrate 120 can comprise or be referred to as a laminate substrate, a ceramic substrate, a rigid substrate, a glass substrate, a silicon substrate, a printed circuit board, a multilayer substrate, or a molded lead frame. In some examples, substrate 120 can comprise or be referred to as a redistribution layer (RDL) substrate, a buildup substrate, or a coreless substrate. The area or “footprint” of substrate 120 can vary based on to the area or number of electronic components 110, 170 located over substrate 120. In some examples, substrate 120 can have an area of about 20 millimeters (mm)×20 mm to about 100 mm×100 mm. Substrate 120 can have a thickness of about 0.1 mm to about 4 mm.

In some examples, substrate 120 can be an RDL substrate. RDL substrates can comprise one or more conductive redistribution layers and one or more dielectric layers and (a) can be formed layer by layer over an electronic device to where the RDL substrate is to be coupled, or (b) can be formed layer by layer over a carrier and can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process and can include one or more dielectric layers alternatingly stacked with one or more conductive layers and define respective conductive redistribution patterns or traces configured to collectively (a) fan-out electrical traces outside the footprint of the electronic device, or (b) fan-in electrical traces within the footprint of the electronic device. The conductive patterns can be formed using a plating process such as, for example, an electroplating process or an electroless plating process. The conductive patterns can comprise a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through where light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrates can comprise one or more inorganic dielectric layers. Some examples of one or more inorganic dielectric layers can comprise silicon nitride (Si3N4), silicon oxide (SiO2), or silicon oxynitride (SiON). The one or more inorganic dielectric layers can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can comprise or be referred to as a coreless substrate.

In some examples, substrate 120 can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate and omits the permanent core structure, and the dielectric and conductive layers can be formed on a sacrificial carrier and is removed after formation of the dielectric and conductive layers and before attachment to the electronic device. The pre-formed substrate can referred to as a printed circuit board (PCB) or a laminate substrate. Such pre-formed substrate can be formed through a semi-additive or modified-semi-additive process. Other substrates in the disclosure can also comprise a pre-formed substrate.

Electronic component 110 can be provided on inward side 121 of substrate 120. In some examples, electronic component 110 can be positioned proximate to the center of inward side 121 of substrate 120. Electronic component 110 can comprise side 111 and side 112. Side 112 of electronic component 110 can be opposite to side 111 of electronic component 110. In some examples, side 111 of electronic component 110 can comprise or be referred to as an active side, and side 112 of electronic component 110 can comprise or be referred to as an inactive side. Electronic component 110 can comprise a sidewall connecting side 111 of electronic component 110 to side 112 of electronic component 110. In some examples, electronic component 110 can comprise or be referred to as a die, a chip, or a package.

Electronic component 110 can comprise contact pads 113. Contact pads 113 can be provided in rows or columns on side 111 of electronic component 110. Contact pads 113 can be input/output terminals of electronic component 110. In some examples, contact pads 113 can be RDL pads exposed through a dielectric material of electronic component 110. In some examples, the dielectric material of electronic component 110 can be silicon nitride (SiN) or silicon dioxide (SiO₂).

Electronic component 110 can comprise connectors 114 coupled to contact pads 113 of electronic component 110. In some examples, connectors 114 can comprise or be referred to as bumps, tin-lead (SnPb) solder bumps, leadfree bumps, copper phosphorus (CuP), stud bumps, pillars, or posts. In some examples, connectors 114 can be provided on contact pads 113 of electronic component 110 by electroless plating, sputtering, deposition such as physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). For example, connectors 114 can be provided so as to be in contact with exposed contact pads 113 of electronic component 110, after a photoresist pattern for exposing contact pads 113 of electronic component 110 is provided on side 111 of electronic component 110. In some examples, the thicknesses of connectors 114 can be from approximately 1.0 μm to approximately 50 μm.

In some examples, pick-and-place equipment can pick up electronic component 110 and place electronic component 110 on inward side 121 of substrate 120. Connectors 114 of electronic component 110 can be positioned on substrate inward terminals 124a. Subsequently, through a reflow process, a thermal compression process, a laser assisted bonding (LAB) process, or a hybrid bonding process, connectors 114 of electronic component 110 can be coupled to substrate inward terminals 124a of substrate 120. Electronic component 110 can be coupled to conductive structure 124 of substrate 120 through connectors 114. In some examples, the overall thickness of electronic component 110 can range from approximately 0.05 mm to approximately 4.0 mm, and the area of electronic component 110 can range from approximately 0.1 mm×0.1 mm to approximately 70 mm×70 mm.

In some examples, electronic component 110 can comprise metallization layer 115 in contact with side 112 of electronic component 110. In some examples, metallization layer 115 can comprise or be referred to as a backside metallization (BSM), a plating layer, a conductive film, or a conductive layer. Metallization layer can comprise one or more layers of, for example, nickel (Ni), copper (Cu), titanium (Ti), or gold (Au).

In some examples, one or more electronic components 170 can be disposed over inward side 121 of substrate 120. Electronic components 170 can positioned outside electronic component 110. For example, electrotonic components 170 can be located laterally between electronic component 110 and the lateral edge of substrate 120. In some examples, one or of more electronic components 170 can comprise a passive component, such as, for example, a capacitor, resistor, inductor, etc. In some examples, one or more of electronic components 170 can comprise an active component such as, for example, a semiconductor die, chip, or package. In some examples, one or more of electronic components 170 can comprise an antenna patch. Component terminals of electronic components 170 can be coupled to substrate inward terminals 124a on inward side 121 of substrate 120. In some examples, one or more of the electronic components can be coupled to substrate outward terminals 124b on outward side 122 of substrate 120. In some examples, electronic components 170 can be electrically coupled to electronic component 110 through conductive structure 124.

FIG. 2B shows electronic device 100 at a later stage of manufacture. In the example shown in FIG. 2B, underfill 130 can be provided between electronic component 110 and substrate 120. Underfill 130 can contact side 111 of electronic component 110 and inward side 121 of substrate 120. In some examples, underfill 130 does not cover the lateral sides of electronic component 110. In other examples, underfill can partially cover or wholly cover the lateral sides of electronic component 110. In some examples, underfill 130 can contact connectors 114 of electronic component 110. Underfill 130 can comprise or be referred to as a dielectric layer or a nonconductive paste or can be free of an inorganic filler. In some examples, underfill 130 can comprise or be referred to as a capillary underfill (CUF), a nonconductive paste (NCP), a nonconductive film (NCF), an anisotropic conductive film (ACF), or an anisotropic conductive paste (ACP).

In some examples, underfill 130 can be cured after being interposed between electronic component 110 and substrate 120. Underfill 130 can prevent or reduce occurrences of electronic component 110 from being separated from substrate 120, for example as a result of physical or chemical impact.

FIG. 2C shows electronic device 100 at a later stage of manufacture. In the example shown in FIG. 2C, thermal interface material (TIM) 140 can be provided on side 112 of electronic component 110, and lid adhesive 156 can be provided on inward side 121 of substrate 120. TIM 140 can contact side 112 of electronic component 110. When electronic component 110 includes metallization layer 115 provided on side 112, bonding strength and thermal conduction between TIM 140 and electronic component 110 can increased (e.g., metallization layer 115 can improve bonding of TIM 140 to electronic component 110 and heat transfer from electronic component 110 to TIM 140). It is to be appreciated that metallization layer 115 can be considered part of electronic component 110, such that contact with a top side of electronic component 110 can mean contact with a metallization layer 115 of electronic component 110. In some examples, TIM 140 can comprise a metallic TIM or a polymer TIM. TIM 140 can comprise a thermally conductive material. Examples of such thermal interface materials include metal alloy materials, such as gallium, gallium alloys such as alloys with indium, tin, or zinc, silver alloys, tin-silver, indium, and indium alloys. The thermally conductive material of TIM 140 allows heat generated by electronic component 110 to be easily transferred to lid 150 (FIG. 1). TIM 140 can be applied to side 112 of electronic component 110 by dispensing or printing. In some examples, TIM 140 can be attached to side 112 of electronic component 110 in the form of a film. The thickness of TIM 140 can range from approximately 10 μm to approximately 300 μm.

Lid adhesive 156 can be provided along the edge of inward side 121 of substrate 120. Lid adhesive 156 can comprise a dielectric material or an electrically conductive material. For example, lid adhesive 156 can comprise a polymer or a solder. Lid adhesive 156 can be applied to inward side 121 of substrate 120 by dispensing or printing. The height of lid adhesive 156 can range from approximately 10 μm to approximately 300 μm.

FIG. 2D shows electronic device 100 at a later stage of manufacture. In the example shown in FIG. 2D, lid 150 can be provided on inward side 121 of substrate 120. Lid 150 can be located over electronic components 110 and 170. Lid 150 can comprise top plate 150a and sidewall 150b. Sidewall 150b can extend downward from the edges (or perimeter) of top plate 150a. In some examples, top plate 150a can comprise a rectangular, square, quadrilateral, or any other desired shape. In some examples, top plate 150a can comprise one or more trenches, one or more protrusions, or one or more fins on the top side of top plate 150a for enhancing heat dissipation efficiency.

In some examples, sidewall 150b can be in the form of a ring extending continuously about the perimeter of top plate 150a or substrate 120. A cavity can be provided inside sidewall 150b and top plate 150a of lid 150. For example, sidewall 150b, top plate 150a, and inward side 121 of substrate 120 can define the cavity. Electronic component 110 can be located in the cavity of lid 150. Lid 150 can cover electronic component 110. In some examples, the lower side of top plate 150a can be coupled to side 112 of electronic component 110 through TIM 140. The lower side of sidewall 150b can be coupled to inward side 121 of substrate 120 through lid adhesive 156.

In accordance with various examples, lid 150 includes lid holes 155. Lid holes 155 can be provided in top plate 150a and can extend between a top facing or outward facing side and a bottom facing or inward facing side of top plate 150a of lid 150. Lid 150 can include two or more lid holes 155. For example, FIGS. 2DA and 2DB show plan views of example lids 150. In the example shown in FIG. 2DA, lid holes 155 can include two lid holes in top plate 150a. In the example shown in FIG. 2DB, lid holes 155 can include three lid holes in top plate 150a. Lid holes 155 can comprise one infilling hole 155a for injecting infilling material 180 as shown in FIG. 2E into the cavity of lid 150 and one or more discharge holes 155b through which a fluid such as air can be discharged in response to injecting infilling material 180. In some examples, lid holes 155 can be provided at symmetric positions around top plate 150a. In some examples, lid holes 155 can also be located at the center of top plate 150a, as shown in FIG. 2DB. While lid holes 155 are illustrated as proximate to the corner regions of top plate 150a, it is further contemplated and understood that the position of infilling hole 155a and discharge hole 155b can be in any desired location in top plate 150a. Further, top plate 150a can include any number of infilling holes 155a and any number of discharge holes 155b. In some examples, lid holes 155 can comprise or be referred to as openings or apertures. In some examples, the sizes or diameters of lid holes 155 can range from approximately 500 μm to approximately 3000 μm.

Lid 150 can be made of a metal with high heat conduction and radiation. For example, lid 150 can comprise aluminum, nickel, or copper. In some examples, lid 150 can comprise or be referred to as a heatsink, a heat dissipation plate, a cap cover, an encapsulation part, a protection part, a package, or a body. While sidewall 150b is shown as non-orthogonal to top plate 150a, it is contemplated and understood that, in some examples, sidewall 150b can be orthogonal to top plate 150a.

FIG. 2E shows electronic device 100 at a later stage of manufacture. In the example shown in FIG. 2E, infilling material 180 can be provided within the cavity of lid 150. Infilling material 180 can be cured after being provided to the cavity of lid 150. Infilling material 180 can be provided into the cavity through lid holes 155 of lid 150. Two or more lid holes 155 can be provided so even when infilling material 180 is injected through one lid hole 155, an internal fluid such as air can be discharged through the other lid holes 155. Since two or more lid holes 155 are provided, generation of voids in infilling material 180 can be prevented or mitigated.

Infilling material 180 can contact sidewalls of electronic component 110, inward side 121 of substrate 120, sidewalls of underfill 130, sidewalls of TIM 140, and electronic components 170. Infilling material 180 can also contact the inner side of lid 150. Infilling material 180 can surround TIM 140. Infilling material 180 can prevent or mitigate separation of TIM 140 from electronic component 110. Infilling material 180 can prevent or mitigate separation of TIM 140 from lid 150. In some examples, infilling material 180 can comprise a covering material that comprises an epoxy adhesive such as a liquid molding compound (LMC), CUF, NCP, or ACP. In some examples, infilling material 180 and TIM 140 can comprise the same material. In other examples, infilling material 180 and TIM 140 can comprise different materials. In some examples, underfill 130 can be eliminated and infilling material 180 can comprise a mold underfill. For example, infilling material 180 can be located between side 111 of electronic component 110 and inward side 121 of substrate 120. In general, TIM 140 and infilling material 180 can be referred to as a covering material.

FIG. 2F shows electronic device 100 at a later stage of manufacture. In the example shown in FIG. 2F, external interconnects 160 can be provided on outward side 122 of substrate 120. External interconnects 160 can be coupled to substrate outward terminals 124b. In some examples, external interconnects 160 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. For example, external interconnects 160 can be provided through a reflow process after forming a conductive material containing a solder on substrate outward terminals 124b by a ball-drop method. External interconnects 160 can comprise or be referred to as conductive balls such as solder balls, conductive pillars such as copper pillars, conductive posts with solder caps formed over the copper pillars, bumps, or pads. In some examples, the sizes of external interconnects 160 can range from approximately 25 μm to approximately 350 μm. In some examples, external interconnects 160 can be referred to as external input/output terminals of electronic device 100. In some examples, electronic device 100 can be a land grid array (LGA) where substrate outward terminals 124b serve as external input/output terminals without external interconnects 160.

In some examples, singulation can be performed to separate substrate 120 into individual electronic devices 100. In some examples, lid 150 can be also cut/diced during singulation. In accordance with various examples, electronic device 100 can comprise electronic component 110, substrate 120, underfill 130, TIM 140, lid 150, external interconnects 160, electronic components 170, and infilling material 180. In electronic device 100, infilling material 180 can prevent or mitigate TIM 140 separating or delaminating from electronic component 110 or lid 150 by reducing thermal stress. For example, infilling material 180 can reduce or eliminate distortion or deformation caused by the coefficient of thermal expansion of substrate 120 being different from the coefficient of thermal expansion of lid 150. Reducing distortion or deformation decreases occurrences of TIM 140 separating from electronic component 110 or lid 150.

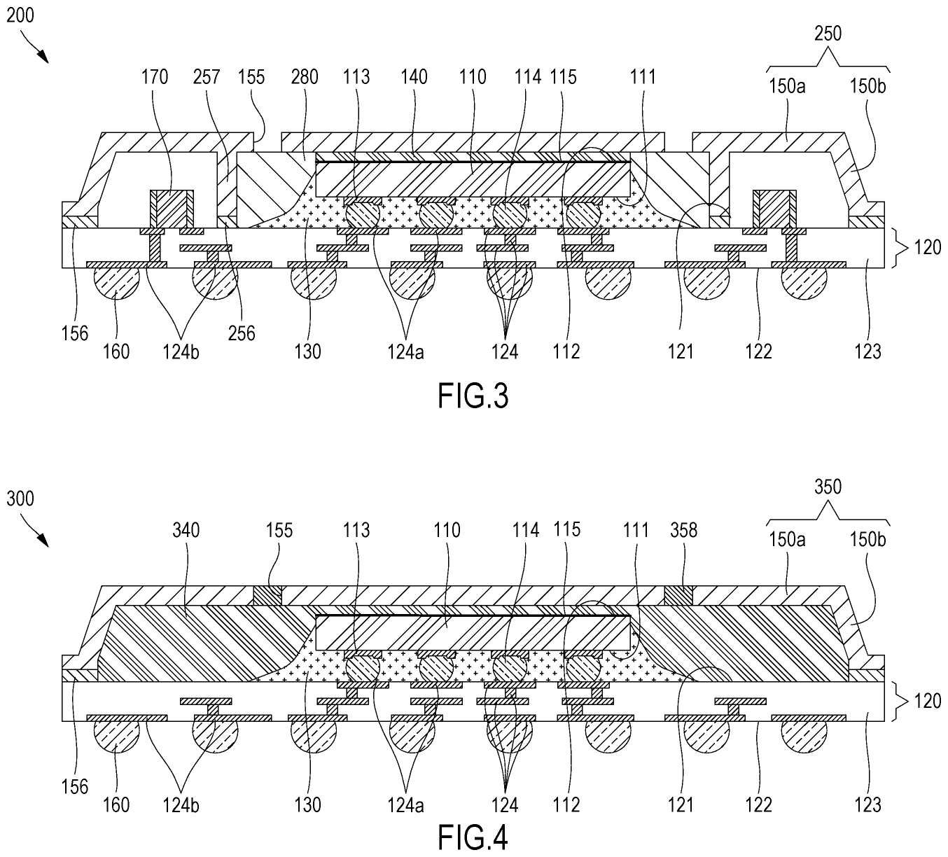

FIG. 3 shows a cross-sectional view of an example electronic device 200. In the example shown in FIG. 3, electronic device 200 can comprise electronic component 110, substrate 120, underfill 130, TIM 140, lid 250, external interconnects 160, electronic components 170, and infilling material 280.

Electronic device 200 can be similar to electronic device 100. For example, electronic device 200 can be similar to electronic device 100 in terms of electronic component 110, substrate 120, underfill 130, TIM 140, external interconnects 160, and electronic components 170. In addition, electronic device 200 can comprise lid 250 and infilling material 280.

Lid 250 can comprise top plate 150a and sidewall 150b extending downward from the edges of top plate 150a. Elements, features, materials, or manufacturing methods of top plate 150a and sidewall 150b of lid 250 can be similar to, or the same as, those of top plate 150a and sidewall 150b, respectively, of lid 150.

Lid 250 can comprise leg 257 spaced apart from sidewall 150b in an inward direction of the lid. Leg 257 can extend downward from top plate 150a of lid 250. Leg 257 can cover the sidewall of electronic component 110. In some examples, leg 257 can comprise a ring extending continuously about electronic component 220. An inward facing sidewall of leg 257 and the inward facing side of top plate 150a can form or define a first cavity or inner cavity of lid 250. An outward facing sidewall of leg 257, the inward facing side of top plate 150a, and an inward facing side of sidewall 150b can form or define a second (or outer) cavity of lid 250. Electronic component 110 can be located in the inner cavity defined by leg 257, for example in the first cavity, and electronic components 170 can be located in the outer cavity between leg 257 and sidewall 150b, for example in the second cavity. The lower side of leg 257 can be coupled to inward side 121 of substrate 120 through lid adhesive 256.

Lid 250 can include lid holes 155 penetrating between the top side and bottom side of top plate 150a. Lid holes 155 can be more centrally located than leg 257 on lid 250. For example, leg 257 can be located between lid hole 155 and the edge of lid plate 150a. Lid holes 155 can be provided in a region between leg 257 and electronic component 110. Elements, features, or manufacturing methods of lid holes 155 of lid 250 can be similar to, or the same as, those of lid holes 155 of lid 150.

Infilling material 280 can be provided in the inner cavity defined by leg 257. Infilling material 280 can contact sidewalls of electronic component 110, inward side 121 of substrate 120, sidewalls of underfill 130, sidewalls of TIM 140, and the inward facing side of lid 250. Infilling material 280 can be in contact with top plate 150a of lid 250 and leg 257. Infilling material 280 can surround TIM 140. Elements, features, materials, or manufacturing methods of infilling material 280 can be similar to, or the same as, those of infilling material 180. In the example shown, since infilling material 280 is provided only in the inner cavity defined leg 257, unnecessary material consumption can be prevented or the weight of device 200 can be reduced. In some examples, leg 257 can allow a conductive material to be employed for infilling material 280, as leg 257 blocks the infilling material from contacting electronic components 170. In some examples, infilling material 280 and TIM 140 can comprise the same material. In other examples infilling material 280 and TIM 140 can comprise different materials. In general, TIM 140 and infilling material 280 can be referred to as a covering material.

FIG. 4 shows a cross-sectional view of an example electronic device 300. In the example shown in FIG. 4, electronic device 300 can comprise electronic component 110, substrate 120, underfill 130, TIM 340, lid 350, and external interconnects 160. Electronic device 300 can be similar to electronic device 100. For example, electronic device 300 can be similar to electronic device 100 in terms of electronic component 110, substrate 120, underfill 130, and external interconnects 160. In the example shown, electronic device 300 can comprise TIM 340 and lid 350. In some examples, electronic device 300 can be devoid of electronic components 170. Lid 350 can comprise lid holes 155, lid adhesive 156, and hole plugs 358. Lid 350 can comprise top plate 150a and sidewall 150b. In general, TIM 340 can be referred to as a covering material.

In some examples, substrate 120 can comprise dielectric structure 123 and conductive structure 124. Electronic component 110 can be over the top side or inward side 121 of substrate 120 and can be coupled with conductive structure 120. Lid 350 can be over substrate 120 and can be coupled with the top side or inward side 121 of substrate 120. Lid 350 can comprise top plate 150a having a plurality of lid holes 155. A covering material such as TIM 340 can cover a lateral side of electronic component 110. The covering material comprising TIM 340 can be between a top side 112 of electronic component 110 and the bottom side of top plate 150a of lid 350. In some examples, the bottom side 111 of electronic component 110 can be free or the covering material comprising TIM 340. In some examples, TIM 340 can comprise a liquid such as a liquid metal. In some examples, TIM 340 can cover or contact sidewall 150b of lid 350.

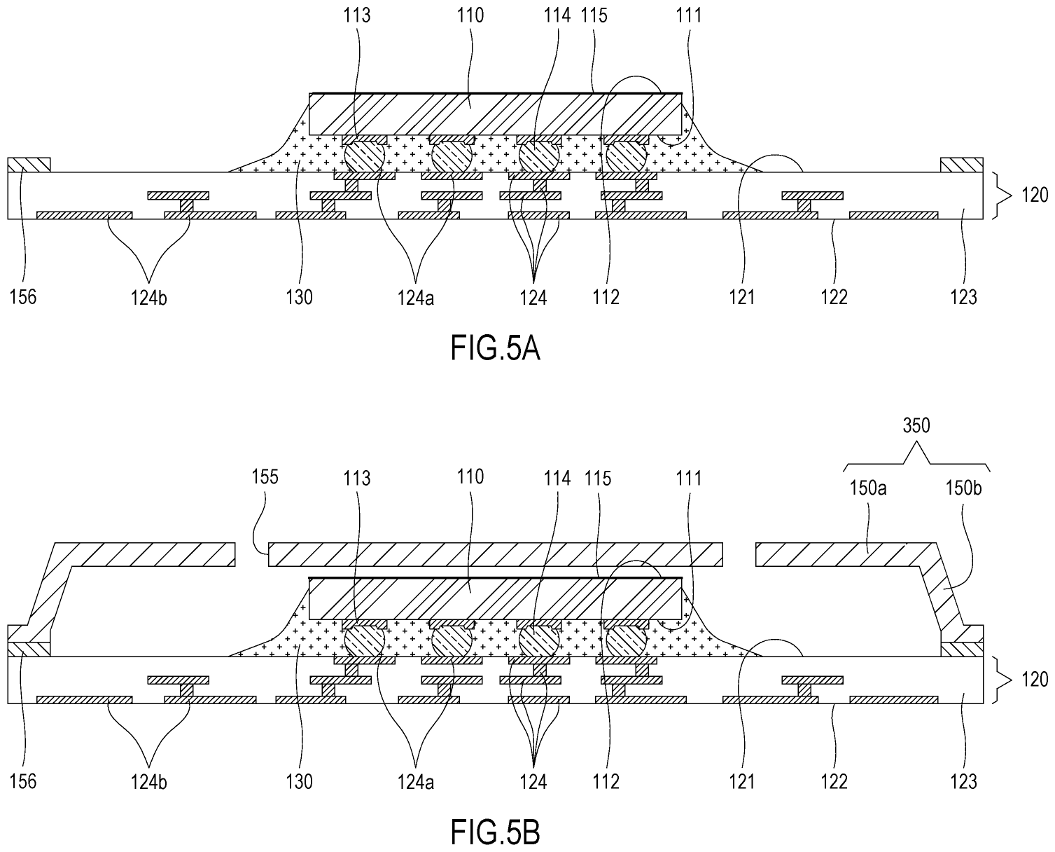

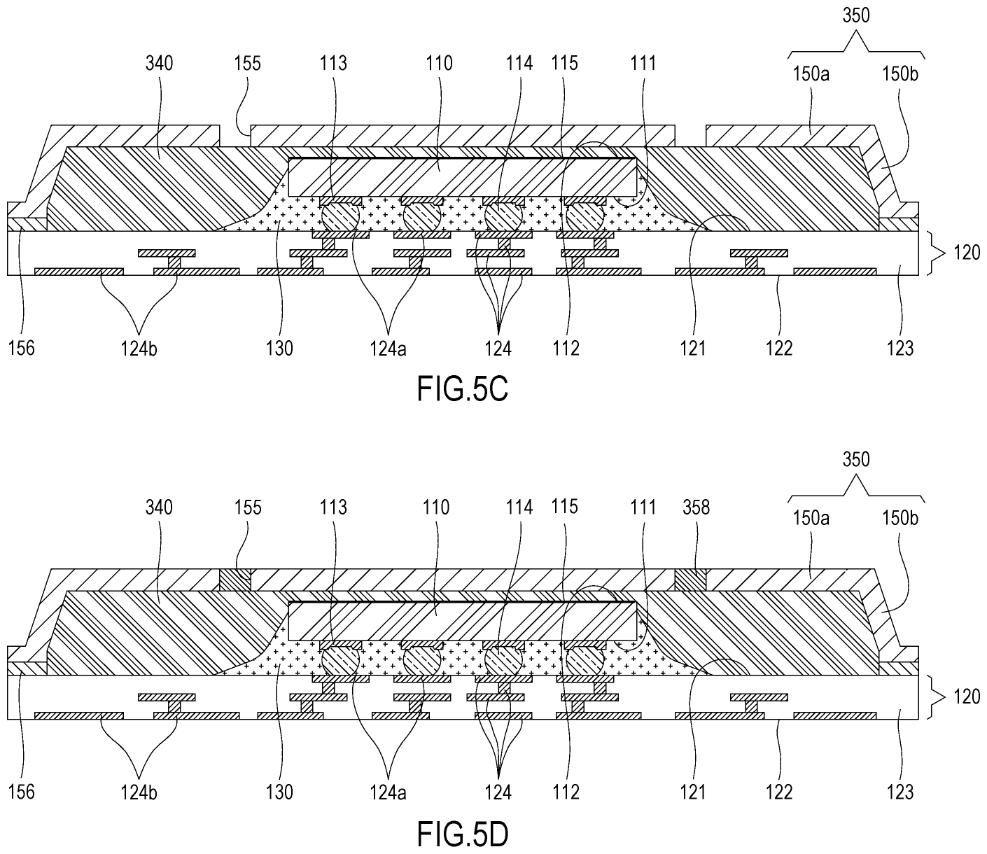

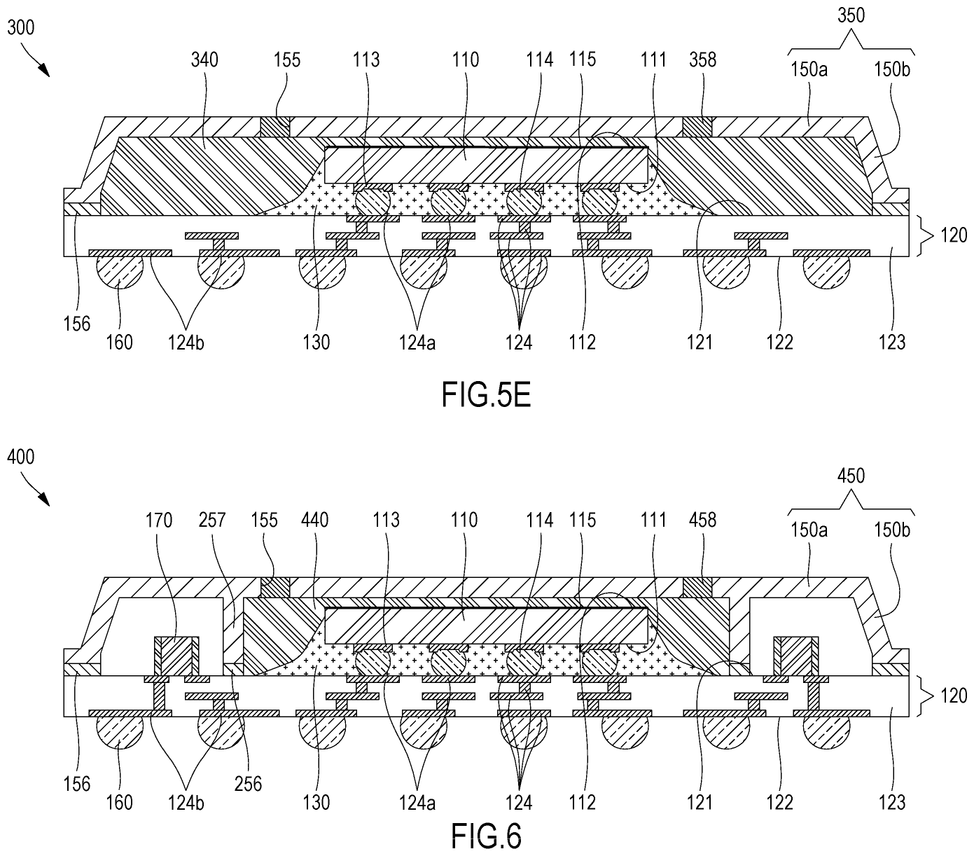

FIGS. 5A to 5E show cross-sectional views of an example method for manufacturing an example electronic device, such as electronic device 300. FIG. 5A shows electronic device 300 at an early stage of manufacture, after a manufacturing process similar to the manufacturing process steps of electronic device 100 shown in FIGS. 2A and 2B. In the example shown in FIG. 5A, lid adhesive 156 can be provided on inward side 121 of substrate 120. Lid adhesive 156 can be provided along the edge of inward side 121 of substrate 120. Elements, features, materials, or manufacturing methods of lid adhesive 156 can be similar to, or the same as, those of lid adhesive 156 of electronic device 100.

FIG. 5B shows electronic device 300 at a later stage of manufacture. In the example shown in FIG. 5B, lid 350 can be provided on inward side 121 of substrate 120. Lid 350 can comprise top plate 150a and sidewall 150b extending downward from top plate 150a. The lower side of sidewall 150b can couple lid 350 to inward side 121 of substrate 120 through lid adhesive 156. Electronic component 110 can be located in a cavity defined by top plate 150a and sidewall 150b of lid 350. Two or more lid holes 155 can be provided in top plate 150a of lid 350. Elements, features, materials, or manufacturing methods of lid 350 can be similar to, or the same as, those of lid 150. In accordance with various examples, the lower side of top plate 150a can be spaced apart from side 112 of electronic component 110.

FIG. 5C shows electronic device 300 at a later stage of manufacture. In the example shown in FIG. 5C, TIM 340 can be deposited in the cavity of lid 350. TIM 340 can contact side 112 and sidewalls of electronic component 110, inward side 121 of substrate 120, the inner side of sidewall 150b, and sidewalls of underfill 130. In some examples, TIM 340 can fill the cavity of lid 350 and contact the lower side of top plate 150a. In some examples, at least a portion of one or more sidewalls of electronic component 110 is exposed from underfill 130, and TIM 340 can contact one or more of the sidewalls of electronic component 110. In some examples, TIM 340 can be interposed between side 112 of electronic component 110 and top plate 150a of lid 350. TIM 340 can transfer heat generated from electronic component 110 to lid 350. When electronic component 110 comprises metallization layer 115, contact or bonding force between TIM 340 and side 112 of electronic component 110 can be enhanced. It is to be appreciated that metallization layer 115 can be considered part of electronic component 110, such that contact with a top side of electronic component 110 can mean contact with a metallization layer 115 of electronic component 110.

Two or more lid holes 155 can be provided in lid 350 so that an internal fluid such as air can be discharged through the other lid holes 155 when TIM 340 is injected through one of the lid holes 155. Since two or more lid holes 155 are provided, generation of voids in TIM 340 can be prevented or mitigated. Elements. features, or manufacturing methods of lid holes 155 in lid 350 can be similar to, or the same as, those of lid holes 155 of lid 150.

In some examples, TIM 340 can comprise a metallic TIM or a polymer TIM. For example, TIM 340 can comprise a thermally conductive material such as a metal material, for example solder or solder paste. The thermally conductive material of TIM 340 allows heat generated from electronic component 110 to be easily transferred to lid 350. In some examples, TIM 340 can comprise a gallium-indium based alloy such as eutectic gallium-indium (EGaIn) or a gallium (Ga), indium (In), and tin (Sn) alloy (e.g., Galinstan®). In some examples, EGaIn can comprise 75.5% by weight Ga and 24.5% by weigh In. In some examples, the Ga, In, and Sn alloy can be comprised of about 68.5% by weight Ga, about 21.5% by weight In, and about 10.0% by weight Sn, as used in the previous context only, the term “about” means±5.0%.

In accordance with various examples, TIM 340 can comprise or be referred to as a covering material that can be in liquid form at room temperature. The liquid state of TIM 340 can allow TIM 340 to remain in contact with lid 350 and electronic component 110 even if distortion or deformation occurs due to a difference in the coefficients of thermal expansion of substrate 120 and lid 350. TIM 340 maintaining contact with electronic component 110 and lid 350 allows heat generated from electronic component 110 to be transferred to lid 350, even in the event of distortion of one or more components of electronic device 300. In this regard, TIM 340 tends to improve the thermal reliability of electronic device 300. In some examples, TIM 340 can contact side 112 of electronic component 100 and also the sidewalls of electronic component 110. In such an arrangement, heat can be dissipated from side 112 of electronic component 110 in a vertical direction into TIM 340, and heat can also be dissipated from the sidewalls of electronic component 110 in a horizontal direction into TIM 340. In some examples, electronic device 300 can include TIM 140 between side 112 of electronic component 110 and top plate 150a, and TIM 340 can surround or contact TIM 140. In general, TIM 340, or a combination of TIM 340 and TIM 140, can be referred to as a covering material.

FIG. 5D shows electronic device 300 at a later stage of manufacture. In the example shown in FIG. 5D, hole plugs 358 can be provided to lid holes 155 of lid 350. Lid holes 155 can be closed and sealed by hole plugs 358. Hole plugs 358 can prevent TIM 340 in the cavity of lid 350 from leaking out lid holes 155. Hole plugs 358 can be made of metal or insulating materials. Hole plugs 358 can be provided by applying solder paste or epoxy adhesive into lid holes 155. Hole plugs 358 can comprise an elastic member, such as rubber, and can be inserted into lid holes 155 in a state of being pressed into lid holes 150. For example, prior to being inserted into lid holes 155, hole plugs 358 can have a larger diameter than lid holes 155 and lid plugs 358 can be held in place by friction coupling. In some examples, an adhesive can be employed to couple lid plugs 358 to top plate 150a.

FIG. 5E shows electronic device 300 at a later stage of manufacture. In the example shown in FIG. 5E, external interconnects 160 can be provided on outward side 122 of substrate 120. Elements, features, materials, or manufacturing methods of external interconnects 160 of electronic device 300 can be similar to, or the same as, those of external interconnects 160 of electronic device 100.

In some examples, singulation can be performed to separate substrate 120 into individual electronic devices 300. In some examples, lid 350 can be also cut/diced during singulation. In accordance with various examples, electronic device 300 can comprise electronic component 110, substrate 120, underfill 130, TIM 340, lid 350, and external interconnects 160. In electronic device 300, it is possible to prevent or mitigate TIM 340 from being separated from electronic component 110 or lid 350. For example, TIM 340 being in liquid form allows TIM 340 to maintain contact with electronic component 110 and lid 350 even in response to distortion or deformation, which can be caused, for example, by a difference in the coefficients of thermal expansion of electronic component 110 and lid 350.

FIG. 6 shows a cross-sectional view of an example electronic device 400. In the example shown in FIG. 4, electronic device 400 can comprise electronic component 110, substrate 120, underfill 130, TIM 440, lid 450, external interconnects 160, and electronic components 170. Electronic device 400 can be similar to electronic device 100. For example, electronic device 400 can be similar to electronic device 100 in terms of electronic component 110, substrate 120, underfill 130, external interconnects 160, and electronic components 170. Electronic device 400 can comprise lid 450 and TIM 440.

In electronic device 400, electronic component 110 can be located in an inner cavity defined by the inward facing side of leg 257 and the inward facing side of top plate 150a, and one or more of electronic components 170 can be located in an outward cavity defined between the outward facing side of leg 257, the inward facing side of top plate 150a, and the inward facing side of sidewall 250b. In some examples, leg 257 can extend from top plate 150a of lid 450 between electronic component 110 and sidewall 150b of lid 450. The lower side of leg 257 can be coupled to the top side or inward side 121 of substrate 120 through lid adhesive 256. Elements, features, materials, or manufacturing methods of lid 450 can be similar to, or the same as, those of lid 250 of electronic device 200. In the present example, lid 450 can comprise hole plugs 458. Elements, features, materials, or manufacturing methods of hole plugs 458 can be similar to, or the same as, those of hole plugs 358 of electronic device 300.

TIM 440 can be inside the inner cavity in which electronic device 110 is located. In some examples, TIM 440 can cover or contact the inward side of leg 257. TIM 440 can cover or contact sidewalls and side 112 of electronic component 110, inward side 121 of substrate 120, sidewalls of underfill 130, and the inner side of lid 450. TIM 440 can be interposed between the lower side of top plate 150a and side 112 of electronic component 110. Elements, features, materials, or manufacturing methods of TIM 440 can be similar to, or the same as, those of TIM 340. In some examples where TIM 440 is provided only in the inward cavity defined by leg 257, unnecessary material consumption can be mitigated or prevented. In such examples, the outward cavity is free of covering material such as TIM 4400. In some examples, electronic component 170 can be free of covering material such as TIM 440. Since TIM 440 is not in contact with electronic components 170, a short circuit can be prevented or mitigated. In some examples, TIM 440 can contact side 112 of electronic component 100 and also the sidewalls of electronic component 110. In some examples, the covering material such as TIM 440 can contact the top side or inward side 121 of substrate 120. In such an arrangement, heat can be dissipated from side 112 electronic component 110 in a vertical direction into TIM 440, and heat can also be dissipated from the sidewalls of electronic component 110 in a horizontal direction into TIM 440. In some examples, electronic device 400 can include TIM 140 between side 112 of electronic component 110 and top plate 150a, and TIM 440 can surround or contact TIM 140. In some examples, sidewall 150b of lid 450 can be free of TIM 440. In general, TIM 440, or a combination of TIM 440 and TIM 140, can be referred to as a covering material.

The present disclosure includes reference to certain examples. It will be understood by those skilled in the art, however, that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

The invention claimed is:

1. An electronic device, comprising:
a substrate comprising a dielectric structure and a conductive structure;
a first electronic component over a top side of the substrate and coupled with the conductive structure;
a lid over the first electronic component and coupled with a top side of the substrate, wherein the lid comprises a top plate having a plurality of holes; and
a covering material covering a lateral side of the first electronic component and extending between the top side of the substrate and a bottom side of the top plate of the lid.

2. The electronic device of claim 1, wherein:
the covering material comprises:
a thermal interface material between the first electronic component and the top plate; and
infilling material surrounding thermal interface material.

3. The electronic device of claim 1, wherein:
the covering material comprises a liquid thermal interface material.

4. The electronic device of claim 1, comprising:
a second electronic component over the top side of the substrate and coupled with the conductive structure;
wherein the covering material covers a lateral side of the second electronic component.

5. The electronic device of claim 1, wherein:
the lid comprises a leg extending from the top plate of the lid and coupled with the top side of the substrate between the first electronic component and a sidewall of the lid;
an inward side of the leg defines a first cavity;
an outward side of the leg and an inward side of the sidewall of the lid define a second cavity;
the first electronic component is in the first cavity; and
the covering material is inside the first cavity and contacts the inward side of the leg.

6. The electronic device of claim 5, comprising:
a second electronic component over the top side of the substrate and in the second cavity;
wherein the second cavity is free of the covering material.

7. The electronic device of claim 5, wherein:
the covering material contacts the top side of the substrate and a top side of the first electronic component.

8. An electronic device, comprising:
a substrate comprising a dielectric structure and a conductive structure;
a first electronic component over a top side of the substrate and coupled with the conductive structure;
a lid over the first electronic component and coupled with a top side of the substrate, wherein the lid comprises a top plate having a plurality of holes; and
a covering material covering a lateral side of the first electronic component.

9. The electronic device of claim 8, wherein:
the covering material is between a top side of the first electronic component and a bottom side of the top plate of the lid; and
a bottom side of the first electronic component is free of the covering material.

10. The electronic device of claim 8, comprising:
hole plugs in the plurality of holes.

11. The electronic device of claim 8, wherein:
the covering material comprises a liquid metal.

12. The electronic device of claim 8, wherein:
the covering material contacts a sidewall of the lid.

13. The electronic device of claim 8, wherein:
the lid comprises a leg extending from the top plate of the lid and coupled with the top side of the substrate between the first electronic component and a sidewall of the lid;
wherein the leg defines a first cavity containing the first electronic component and a second cavity between the leg and the sidewall; and
wherein the covering material is in the first cavity and contacts a lateral side of the leg.

14. The electronic device of claim 13, wherein:
the sidewall of the lid is free of the covering material.

15. The electronic device of claim 13, comprising:
a second electronic component over the top side of the substrate and coupled with the conductive structure;
wherein the second electronic component is in the second cavity and is free of the covering material.

16. A method to manufacture an electronic device, comprising:
providing a substrate comprising a dielectric structure and a conductive structure;
providing a first electronic component over a top side of the substrate and coupled with the conductive structure;
providing a lid over the first electronic component and coupled with a top side of the substrate, wherein the lid comprises a top plate having a plurality of holes; and
providing a covering material into one of the plurality of holes;
wherein the covering material covers a lateral side of the first electronic component and extends from the top side of the substrate to the top plate of the lid.

17. The method of claim 16, comprising:
providing a thermal interface material between a top side of the first electronic component and a bottom side of the lid;
wherein the covering material comprises an infilling material that is different from the thermal interface material.

18. The method of claim 16, wherein:
the covering material comprises a thermal interface material; and
the thermal interface material is between a top side of the first electronic component and a bottom side of the lid and contacts a sidewall of the lid.

19. The method of claim 16, wherein:
the lid comprises a leg extending from the top plate of the lid and coupled with the top side of the substrate between the first electronic component and a sidewall of the lid;
wherein the leg defines a first cavity containing the first electronic component and a second cavity between the leg and the sidewall; and
wherein the covering material is in the first cavity and contacts a lateral side of the leg.

20. The method of claim 19, comprising:
providing a second electronic component over the top side of the substrate and coupled with the conductive structure;
wherein the second electronic component is in the second cavity and is free of the covering material.
